(19) United States
(12) Patent Application Publication
(10) Pub. No.: US 2024/0219533 A1
(43) Pub. Date: Jul. 4, 2024

(54) LIDAR DEVICE, RECEIVER THEREFOR, AND OPERATING METHOD THEREOF

(71) Applicant: SAMSUNG ELECTRONICS CO., LTD., Suwon-si (KR)

(72) Inventor: Hankyu LEE, Suwon-si (KR)

(73) Assignee: SAMSUNG ELECTRONICS CO., LTD., Suwon-si (KR)

(21) Appl. No.: 18/216,727

(22) Filed: Jun. 30, 2023

(30) Foreign Application Priority Data
Jan. 4, 2023 (KR) 10-2023-0001324

(51) Int. Cl. G01S 7/4865; G01S 7/484; G01S 7/4861; G01S 17/10

(52) U.S. Cl. CPC G01S 7/4866; G01S 7/484; G01S 7/4861; G01S 17/10

(57) ABSTRACT

The present disclosure provides methods and apparatuses for performing light detection and ranging (LiDAR). In some embodiments, a device includes a light transmitter configured to radiate, to an object, light comprising a transmission signal, a light receiver configured to receive light reflected from the object, an integrator configured to obtain, by integrating a reception signal obtained from the received light, an analog signal corresponding to a convolution result between the reception signal and the transmission signal, and a processor configured to measure, by a time-of-flight (ToF) method, a distance from the device to the object, based on the analog signal.

### CROSS-REFERENCE TO RELATED APPLICATION

This application claims benefit of priority under 35 U.S.C. § 119 to Korean Patent Application No. 10-2023-0001324, filed on Jan. 4, 2023, in the Korean Intellectual Property Office, the disclosure of which is incorporated by reference herein in its entirety.

### BACKGROUND

### 1. Field

The present disclosure relates generally to object detection and ranging, and more particularly, to a light detection and ranging (LiDAR) device, a receiver therefor, and an operating method thereof.

### 2. Description of the Related Art

Light detection and ranging (LiDAR) devices may be used in various fields such as, but not limited to, aerospace, geology, three-dimensional (3D) mapping, automobiles, robots, drones, and the like. A LIDAR device may use a method of measuring a time-of-flight (ToF) of light to measure a distance to an object. For example, the LiDAR device may transmit light to an object, receive light back from the object through a sensor, and measure a ToF thereof by using a high-speed electric circuit. Alternatively or additionally, the LiDAR device may calculate a distance to the object, based on the ToF, and/or may generate a depth image of the object by using the distance calculated for each position of the object.

### SUMMARY

Light detection and ranging (LIDAR) devices, receivers therefor, and operating methods thereof are disclosed by the present disclosure. Aspects of the present disclosure provide for a LiDAR device capable of increasing a distance measurement resolution and a scanning speed (e.g., frames per second) by rapidly and efficiently calculating a time-of-flight (ToF), a receiver therefor, and an operating method thereof. The technical problems to be solved by the disclosure are not limited to the technical problems described above, and other technical problems may be derived from the following embodiments.

According to an aspect of the present disclosure, a device for performing LIDAR is provided. The device includes a light transmitter configured to irradiate, to an object, light including a transmission signal, a light receiver configured to receive light reflected from the object, an integrator configured to obtain, by integrating a reception signal obtained from the received light, an analog signal corresponding to a convolution result between the reception signal and the transmission signal, and a processor configured to measure, by a ToF method, a distance from the device to the object, based on the analog signal.

According to an aspect of the present disclosure, a receiving device for performing LiDAR is provided. The receiving device includes an amplifier configured to obtain a reception signal by converting and amplifying an electrical signal corresponding to light reflected from an object, and an integrator configured to obtain an analog signal corresponding to a convolution result between the reception signal and a transmission signal by integrating the reception signal. The transmission signal is included in light irradiated to the object and the analog signal is used to measure a distance from the receiving device to the object by a ToF method.

According to an aspect of the present disclosure, an operating method of a device for performing LiDAR is provided. The operating method includes irradiating, to an object, light including a transmission signal. The operating method further includes receiving light reflected from the object. The operating method further includes obtaining, by using an integrator to integrate a reception signal obtained from the received light, an analog signal corresponding to a convolution result between the reception signal and the transmission signal. The operating method further includes measuring, by a ToF method, a distance from the device to the object, based on the analog signal.

Additional aspects may be set forth in part in the description which follows and, in part, may be apparent from the description, and/or may be learned by practice of the presented embodiments of the disclosure.

### BRIEF DESCRIPTION OF THE DRAWINGS

The above and other aspects, features, and advantages of certain embodiments of the disclosure may be more apparent from the following description taken in conjunction with the accompanying drawings, in which:

FIG. 1 is a diagram illustrating a light detection and ranging (LiDAR) device, according to an embodiment;

FIG. 2 is a diagram depicting a convolution between a reception signal and a transmission signal, according to an embodiment;

FIG. 3 is a diagram illustrating a reception signal and a transmission signal, according to an embodiment;

FIG. 4 is a diagram depicting an example of an integrator, according to an embodiment;

FIG. 5 is a diagram illustrating an integrator, according to an embodiment;

FIG. 6 is a diagram illustrating an analog circuit including an integrator, according to an embodiment;

FIG. 7 is a diagram illustrating simulation results with respect to an integrator implementing a convolution, according to an embodiment;

FIG. 8 is a block diagram illustrating a configuration of a LIDAR device, according to an embodiment;

FIG. 9 is a block diagram illustrating a configuration of a receiver, according to an embodiment; and

FIG. 10 is a flowchart illustrating an operating method of a LIDAR device, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases.

The terms used herein are those general terms currently widely used in the art in consideration of functions in regard to the disclosure, but the terms may vary according to the intentions of those of ordinary skill in the art, precedents, or new technology in the art. Also, in certain cases, there may be terms optionally selected, and in this case, the terms used herein are those general terms currently widely used in the art in consideration of functions in regard to the disclosure, but the terms may vary according to the intentions of those of ordinary skill in the art, precedents, or new technology in the art. Also, in some cases, there may be terms that are optionally selected, and the meanings thereof will be described in detail in the corresponding portions of the description of the embodiment. Thus, the terms used herein are not simple terms and should be defined based on the meanings thereof and the overall description of the present embodiments.

In the descriptions of the embodiments, when an element is referred to as being “connected” to another element, it may be “directly connected” to the other element or may be “electrically connected” to the other element with one or more intervening elements therebetween. Also, when something is referred to as “including” a component, another component may be further included unless specified otherwise.

The term such as “comprise” or “include” used herein should not be construed as necessarily including all of the elements or operations described herein, and should be construed as not including some of the described elements or operations or as further including additional elements or operations.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The following description of embodiments should not be construed as limiting the scope of the disclosure, and those that may be easily inferred by those of ordinary skill in the art should be construed as being included in the scope of the embodiments. Hereinafter, embodiments are described in detail merely as examples with reference to the accompanying drawings.

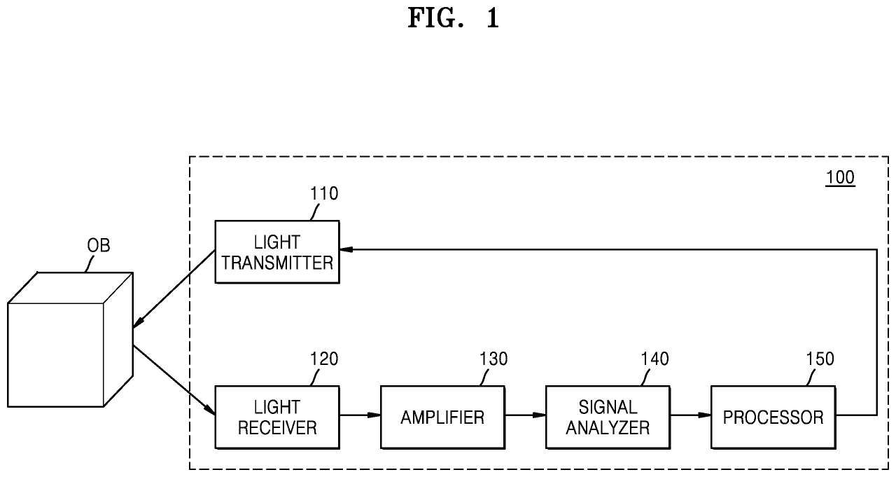

FIG. 1 is a diagram illustrating a light detection and ranging (LiDAR) device, according to an embodiment.

A LIDAR device 100 may be used as a sensor for obtaining three-dimensional (3D) information, such as, but not limited to, distance information about an object OB in front thereof in real time. For example, the LiDAR device 100 may be applied to fields such as, but not limited to, unmanned cars, autonomous driving cars, robots, drones, and the like. For example, the LiDAR device 100 may be a device using LiDAR.

As shown in FIG. 1, the LiDAR device 100 may include a light transmitter 110, a light receiver 120, an amplifier 130, a signal analyzer 140, and a processor 150. Only components related to the present embodiments may be illustrated in the LiDAR device 100 illustrated in FIG. 1. It may be apparent to those of ordinary skill in the art that the LiDAR device 100 may further include other components in addition to the components illustrated in FIG. 1.

The number and arrangement of components of the LiDAR device 100 shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Alternatively or additionally, a set of (one or more) components shown in FIG. 1 may be integrated with each other, and implemented as an integrated circuit, as software, and/or a combination of circuits and software. For example, two or more of the light transmitter 110, the light receiver 120, the amplifier 130, the signal analyzer 140, and the processor 150 may be integrated into a single module. Alternatively or additionally, at least one of the light transmitter 110, the light receiver 120, the amplifier 130, the signal analyzer 140, and the processor 150 may be divided into a plurality of subdivided modules.

The light transmitter 110 may irradiate light to the object OB in order to analyze at least one of the position, shape, distance, and the like of the object OB. The light transmitter 110 may include a light source for irradiating light. For example, the light source may be a device for irradiating light in the infrared region. In the case of using light in the infrared region, mixing with natural light in the visible region including sunlight may be prevented. However, the disclosure is not necessarily limited thereto, and the light transmitter 110 may include a light source for irradiating light of various wavelength bands and/or may irradiate light of a plurality of different wavelength bands.

The light transmitter 110 may be and/or may include a light source such as, but not limited to, a laser diode (LD), an edge emitting laser, a vertical-cavity surface emitting laser (VCSEL), a distributed feedback laser, a light emitting diode (LED), and a super luminescent diode (SLD). However, the disclosure is not limited thereto. According to some embodiments, the light transmitter 110 may be included in another device and may not necessarily be configured as hardware included in the LiDAR device 100.

As an example, the light transmitter 110 may irradiate light (e.g., a laser pulse) generated based on a transmission signal to the object OB. The transmission signal may determine the characteristics of light irradiated to the object. The light transmitter 110 may set an irradiation direction and/or an irradiation angle of light under control by the processor 150. In an embodiment, the light transmitter 110 may further include a beam steering element for changing the irradiation angle of light. For example, the beam steering element may be implemented as a scanning mirror, an optical phased array, and the like.

In an embodiment, the light receiver 120 may output an electric signal by detecting light reflected by and/or scattered from the object OB. For example, the light receiver 120 may convert light reflected and/or scattered from the object OB into a voltage signal and/or a current signal. The light receiver 120 may be and/or may include a light receiving element for generating an electric signal by light energy. The type of light receiving element is not particularly limited. For example, the light receiver 120 may include, but not be limited to, at least one of a photodiode (PD), an avalanche photodiode (APD), and a single-photon avalanche diode (SPAD).

The amplifier 130, according to an embodiment, may obtain a reception signal by converting and/or amplifying the electric signal output from the light receiver 120. For example, the amplifier 130 may include at least one of a transimpedance amplifier (TIA) for converting a current signal into a voltage signal and/or a variable gain amplifier (VGA) for amplifying an electric signal with a variable gain. When the amplifier 130 includes both the TIA and the VGA, the arrangement order of the TIA and the VGA may not be limited.

In an embodiment, the signal analyzer 140 may analyze the time-of-flight (ToF) of light with respect to the object OB by performing signal processing on the reception signal obtained by the amplifier 130. For example, the signal analyzer 140 may detect the ToF of light by using the correlation between the reception signal and the transmission signal. Because the reception signal is a signal obtained by the light receiver 120 as the light that has been generated based on the transmission signal is reflected from the object, the reception signal may have characteristics substantially similar and/or equal to those of the transmission signal. Thus, when a time point at which the correlation between the reception signal and the transmission signal is highest is detected, a time point at which the light irradiated from the light transmitter 110 is received back by the light receiver 120 may be detected and the ToF of the light may be detected.

The processor 150, according to an embodiment, may control an overall operation of various hardware and/or software components included in the LiDAR device 100. For example, the processor 150 may be implemented as at least one of an operation processor (e.g., a central processing unit (CPU), a graphic processing unit (GPU), a neural processing unit (NPU), a microcontroller unit (MCU), an application processor (AP), or the like) including a dedicated logic circuit (e.g., a field programmable gate array (FPGA), an application specific integrated circuit (ASIC), or the like). However, the disclosure is not limited thereto.

In an embodiment, the processor 150 may measure a distance to the object OB based on the ToF measured by the signal analyzer 140 and perform data processing for analyzing the position and/or shape of the object OB. For example, the processor 150 may generate a depth image of the object OB based on the measured distance.

Information about the shape and/or position of the object OB analyzed by the processor 150 may be transmitted to other units to be used. For example, the information may be transmitted to autonomous driving devices such as, but not limited to, autonomous driving cars and/or drones in which the LiDAR device 100 is used. Alternatively or additionally, the information may be transmitted to computing devices such as, but not limited to, desktop computers, computer servers, virtual machines, network appliances, mobile devices (e.g., smart phones, tablets, laptops, personal computers (PCs), personal digital assistants (PDAs), and the like), wearable devices (e.g., smart watches, headsets, headphones, eye glasses, and the like), smart devices (e.g., voice-controlled virtual assistants, set-top boxes (STBs), refrigerators, air conditioners, microwave ovens, televisions, and the like), Internet-of-Things (loT) devices, and/or any other type of data processing devices.

The LiDAR device 100 may further include a memory for storing programs and other data for operations performed by the processor 150. The memory may be hardware for storing various data processed in the LiDAR device 100. For example, the memory may store data processed by the LiDAR device 100 and/or data to be processed. Alternatively or additionally, the memory may store applications, drivers, and the like to be driven by the LiDAR device 100. The memory may be and/or may include, but not be limited to, random access memories (RAMs) such as dynamic random access memories (DRAMs) or static random access memories (SRAMs), read-only memories (ROMs), electrically erasable programmable read-only memories (EEPROMs), compact-disc ROMs (CD-ROMs), Blu-rays, other optical disk storages, hard disk drives (HDDs), solid state drives (SSDs), or flash memories and may further include other external storage devices that may be accessed by the LiDAR device 100.

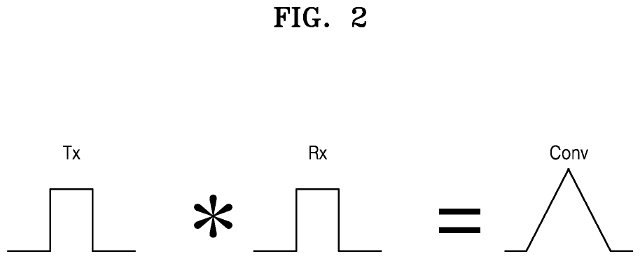

In an embodiment, the convolution between the reception signal and the transmission signal may be used in a process in which the LiDAR device 100 detects the ToF of light by using the correlation between the reception signal and the transmission signal. Hereinafter, a process of detecting the ToF by using the convolution between the reception signal and the transmission signal is described with reference to FIG. 2.

FIG. 2 is a diagram depicting a convolution between a reception signal and a transmission signal, according to an embodiment.

Referring to FIG. 2, a signal Conv corresponding to the convolution result between a reception signal Rx and a transmission signal Tx is illustrated.

The signal Conv corresponding to the convolution result may include a peak, and a time point at which the peak occurs may correspond to a ToF. Thus, the ToF may be obtained by performing peak detection on the signal Conv corresponding to the convolution result.

In an embodiment, the convolution may be performed directly in the time domain. Alternatively or additionally, the convolution may be performed after transformation into the frequency domain. When the convolution is performed in the frequency domain, the transmission signal Tx and the reception signal Rx may be multiplied by each other after being transformed into the frequency domain through a Fast Fourier Transform (FFT) and/or the convolution result may be restored back into the time domain through an Inverse Fast Fourier Transform (IFFT). Typically, a related LIDAR device may perform light detection and ranging by a digital method. The digital method may refer to performing signal processing on digital signals after converting each of the transmission signal Tx and the reception signal Rx into respective digital signals.

For example, the related LiDAR device may perform convolution, peak detection, and ToF measurement by using a digital signal processor (DSP) arranged after an analog-to-digital converter (ADC). However, the digital method may require a significant amount of computing resources (e.g., processor throughput, memory footprint, processing time, power consumption) to perform convolutions involving a significant amount of operations.

Aspects of the present disclosure provide for a method of performing, in the analog domain, a convolution operation necessary for measuring the ToF, by using an analog circuit rather than a DSP that may be used by a related LiDAR device. By performing the convolution in the analog domain, the computing resources required to perform the convolution may be significantly reduced when compared to performing the convolution in the digital domain. For example, performing the convolution in the analog domain may not require a processor and/or a memory and the power required to perform the convolution may be significantly less than the power required to perform the convolution in the digital domain.

According to various embodiments of the present disclosure a method of implementing a convolution operation by using an analog integrator is provided, and a particular methodology thereof is described below.

The convolution operation may be represented as an equation similar to Eq. 1.

$$( f * g ) ( t ) := {\int }_{- ∞}^{∞} f ( τ ) g ( t - τ ) d τ \qquad [ Eq . 1 ]$$

Referring to Eq. 1, f(t) and g(t) may represent the two signals being convoluted. As may be seen from the −τ term on the right side of Eq. 1, one of the convoluted signals should be shifted in the time domain. Consequently, a memory function may be required for a convolution operation to store the time-shifted values. Thus, generally, a convolution operation may be difficult to perform in the analog domain without including a memory function.

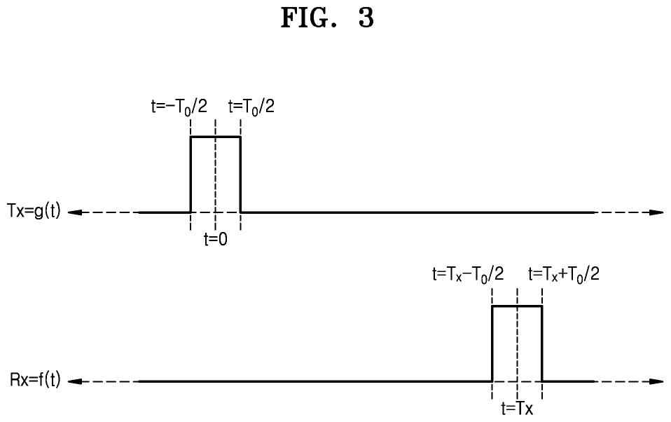

However, the disclosure assumes a case where the shape of a transmission signal (e.g., a square wave pulse) is accurately known, and thusly, a convolution operation may be simulated in the analog domain without the use of a memory function. Hereinafter, a method of implementing a convolution operation in the analog domain is described with reference to FIGS. 3 to 7.

FIG. 3 is a diagram illustrating a reception signal and a transmission signal, according to an embodiment.

Referring to FIG. 3, a reception signal Rx and a transmission signal Tx are illustrated. The reception signal Rx and the transmission signal Tx may be respectively referred to as f(t) and g(t). The functions f(t) and g(t) may be represented as equations similar to Eqs. 2 and 3, respectively.

$$f ( t ) = \{ \begin{matrix}1 , & {T}_{x} - \frac{{T}_{0}}{2} \leq t \leq {T}_{x} + \frac{{T}_{0}}{2} \\ 0 , & otherwise\end{matrix} \} \qquad [ Eq . 2 ]$$

$$g ( t ) = \{ \begin{matrix}1 , & - \frac{{T}_{0}}{2} \leq t \leq \frac{{T}_{0}}{2} \\ 0 , & otherwise\end{matrix} \} \qquad [ Eq . 3 ]$$

In Eqs. 2 and 3, To may represent the width of an applied transmission signal, and T_{X} may represent a ToF to be known. When the transmission signal Tx and the reception signal Rx correspond to square wave pulses, because the function values of f(t) and g(t) may include only size changes, both functions may be simplified as outputting a function value of one (1). When h(t) is defined as the convolution between f(t) and g(t), h(t) may be represented as an equation similar to Eq. 4.

$$h ( t ) = ( f * g ) ( t ) = {\int }_{- ∞}^{∞} f ( τ ) g ( t - τ ) d τ \qquad [ Eq . 4 ]$$

Referring to Eq. 4, because g(t) is an even function that is horizontally symmetrical, Eq. 4 may be converted to an equation similar to Eq. 5.

$$h ( t ) = ( f * g ) ( t ) = {\int }_{- ∞}^{∞} f ( τ ) g ( τ - t ) d τ \qquad [ Eq . 5 ]$$

Referring to Eq. 5, when an integration interval is limited to an interval in which g(τ−t)=1 and g(τ−t) is substituted by 1, Eq. 5 may be converted to an equation similar to Eq. 6.

$$h ( t ) = {\int }_{t - \frac{{T}_{0}}{2}}^{t + \frac{{T}_{0}}{2}} f ( τ ) d τ \qquad [ Eq . 6 ]$$

In other words, h(t) may be equal to a value obtained by integrating f(t) over a time interval of [t−T₀/2,t+T₀/2]. Consequently, a result equivalent to a convolution operation may be obtained by using a simple integrator. In actual implementation, because an interval including t+T₀/2 corresponds to the future, that portion of the interval may not be integrated in the analog domain. Thus, as represented by Eq. 7, a method of obtaining an actual ToF by subtracting T₀/2 from the ToF obtained by integrating over a time interval of [t−T₀,t] may be used.

$$h ( t + \frac{{T}_{0}}{2} ) = {\int }_{t - {T}_{0}}^{t} f ( τ ) d τ \qquad [ Eq . 7 ]$$

As such, a convolution operation may be simulated by using an integrator capable of integrating a signal during a time interval with a preset time length from past to present (e.g., a recent T₀ interval). As long as the integrator may integrate a signal during a time interval with a preset time length from past to present, the integrator may be used without limitation in the structure thereof. As time passes, because the time point designated by the present time changes continuously, and the integration interval slides accordingly, the integrator may be referred to as a moving integrator.

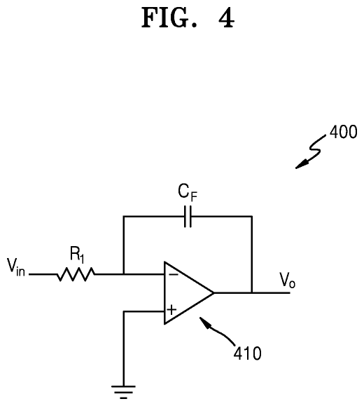

FIG. 4 is a diagram depicting an example of an integrator, according to an embodiment.

Referring to FIG. 4, an example of an integrator 400 having a simple structure including a resistor R₁, a capacitor C_{F}, and an operational amplifier 410 is illustrated. An output signal V₀ of the integrator 400 may be calculated with an equation similar to Eq. 8.

$${V}_{0} = - \frac{1}{{R}_{1} {C}_{F}} {\int }_{- ∞}^{t} {V}_{i n} dt \qquad [ Eq . 8 ]$$

However, because the integrator 400 outputs the result of integrating a given input signal Vᵢₙ during a time interval of [∞,t], the output of the integrator 400 may be different from the result of integration during a time interval of [t−T₀,t] as in Eq. 7 above. Thus, the integrator 400 may not be used as it is in order to simulate a convolution operation.

Here, the characteristics of Vᵢₙ=f(t), that is, having a value of one (1) in an interval [T_{X}−T₀/2, T_{X}+T₀/2] and having a value of zero (0) in all the other intervals, may be considered. In other words, when a decay time of V₀, that is, a time taken for the output V₀ to return to zero (0) by itself, may be adjusted to T₀, an integration over an interval of [t−T₀,t] may be simulated.

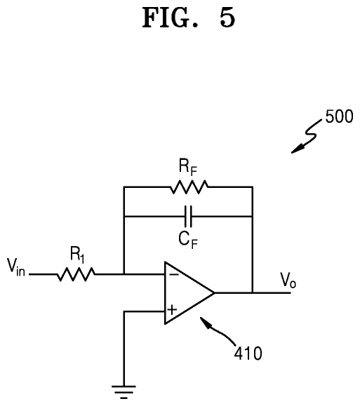

FIG. 5 is a diagram illustrating an integrator, according to an embodiment.

Referring to FIG. 5, an integrator 500 may include or may be similar in many respects to the integrator 400 of FIG. 4 and may include additional features not mentioned above.

For example, the integrator 500 may include a resistor-capacitor low-pass filter (RC LPF) (e.g., formed by R_{F} and C_{F}). Thusly, an output V₀ of the integrator 500 may start to decay due to a leakage current by a resistor R_{F} from the moment of Vᵢₙ=f(t)=0, that is, t=T_{X}+T₀/2. When the impedance values of the passive elements of resistor R₁, resistor R_{F}, and capacitor C_{F} are adjusted based on T₀, a time taken for the output V₀ of the integrator 500 to reach zero (0) may be adjusted, and accordingly, an integration over an interval of [t−T₀,t] may be simulated. For example, when R₁=0.1×R_{F}, the impedance values of the resistor R_{F} and capacitor C_{F} may be adjusted to R_{F}×C_{F}=(⅓ to ⅔)×T₀. However, the disclosure is not limited thereto.

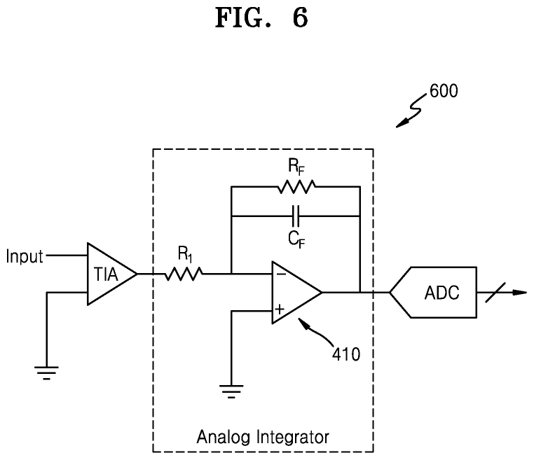

FIG. 6 is a diagram illustrating an analog circuit including an integrator, according to an embodiment.

Referring to FIG. 6, an example of an analog circuit 600 including an analog integrator (e.g., the integrator 500 of FIG. 5) is illustrated. The analog circuit 600 may include a TIA for converting an input current signal into a voltage signal, an analog integrator, and an ADC. In an embodiment, the analog circuit 600 may further include a VGA (not shown). The VGA may be arranged at a certain position of the front end and/or the rear end of the analog integrator and/or may be integrated with the analog integrator.

Because the analog integrator integrates a signal in the analog domain, it may output an analog signal. As described above, the analog signal output from the analog integrator may correspond to the convolution result between the reception signal and the transmission signal of the LiDAR device. The analog signal output from the analog integrator may be converted into a digital signal by the ADC. The digital signal may be processed by a digital circuit (e.g., DSP) connected to the output of the analog circuit 600. For example, the DSP may detect the time at which a peak occurs in the digital signal, and the ToF may be determined based on the detected time. Alternatively or additionally, a distance to the object may be measured based on the ToF.

As such, according to the disclosure, because the convolution operation requiring a large amount of operations in the ToF measurement process of the LiDAR device may be performed in real time in the analog domain instead of the digital domain, the time taken to measure the ToF may be significantly reduced.

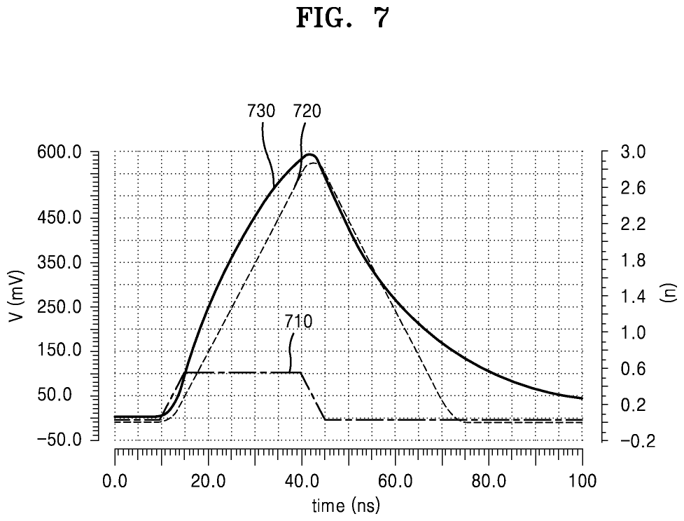

FIG. 7 is a diagram illustrating an actual simulation result of an integrator implementing a convolution, according to an embodiment.

Referring to FIG. 7, for example, when an input signal 710 is a square wave pulse having a rising/falling time of 5 ns and a width of 25 ns, an output signal 720 of an ideal integrator and an output signal 730 of an analog integrator (e.g., the integrator 500 of FIG. 5) are illustrated. Because the output signal 730 has the shape of a triangular wave and has substantially the same peak time as the output signal 720, it may be seen that the convolution operation used to measure the ToF may be simulated by the analog integrator according to the disclosure.

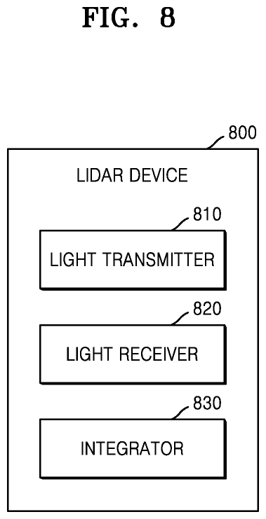

FIG. 8 is a block diagram illustrating a configuration of a LIDAR device, according to an embodiment.

Referring to FIG. 8, a LIDAR device 800 may include a light transmitter 810, a light receiver 820, and an integrator 830. Only components related to the present embodiments are illustrated in the LiDAR device 800 illustrated in FIG. 8. It may be apparent to those of ordinary skill in the art that the LiDAR device 800 may further include other general-purpose components in addition to the components illustrated in FIG. 8.

The light transmitter 810 may irradiate light including a transmission signal to an object, and the light receiver 820 may receive light reflected from the object. Because the light transmitter 810 and the light receiver 820 correspond to the light transmitter 110 and the light receiver 120 of FIG. 1, redundant descriptions thereof will be omitted for the sake of brevity.

The transmission signal may include at least one of a single pulse and a pulse train of a square wave. Because a reception signal shares the characteristics of the transmission signal, it may be apparent that the reception signal may have the shape of a square wave. It has been described above with reference to FIGS. 3 to 7 that the convolution operation may be simulated by the integrator when the transmission signal is a single pulse of a square wave. However, even when the transmission signal is a pulse train including a plurality of square wave pulses, the same description may also be applied when only a certain condition is satisfied.

For example, when the interval between two adjacent pulses among a plurality of pulses included in the pulse train is equal to or greater than the width of each of the plurality of pulses (e.g., T₀ of FIG. 3), convolution signals by two adjacent pulses may be substantially distinguished and the ToF of each of the plurality of pulses may be normally measured. In the integrator 500 of FIG. 5, assuming that T₀=30 ns, R_{F}=40 kΩ, C_{F}=0.25 pF to 0.5 pF, and R₁=4 kΩ, when R_{F}×C_{F}=⅓T₀, the interval between pulses may decrease to T₀, and when R_{F}×C_{F}=⅔T₀, the interval between pulses may increase to 2T₀. In other words, the interval between two adjacent pulses among the plurality of pulses included in the pulse train may be between about T₀ and about 2T₀. However, the disclosure is not limited thereto.

The integrator 830 may obtain an analog signal corresponding to the convolution result between the reception signal and the transmission signal by integrating the reception signal obtained from the received light. The analog signal may be used to measure a distance to the object by a ToF method. The integrator 830 may perform a convolution operation necessary for measuring the ToF in the analog domain.

The integrator 830 may integrate the reception signal during a time interval with a preset time length from past to present. As long as the integrator 830 may integrate a signal during a time interval with a preset time length from past to present, the integrator 830 may be used without limitation in the structure thereof. The preset time length may correspond to the width of a pulse included in the transmission signal (e.g., T₀ of FIG. 3). The integrator 830 may be referred to as a moving integrator sliding in an integration interval.

The integrator 830 may include at least one active element and a plurality of passive elements. The at least one active element may include at least one operational amplifier, and the plurality of passive elements may include at least one resistor and at least one capacitor. However, the disclosure is not limited thereto.

The impedance values of the plurality of passive elements included in the integrator 830 may be determined such that the time taken for the output of the integrator 830 to decay to an initial value (e.g., zero (0)) is close to the width of the pulse included in the transmission signal (e.g., T₀ of 3). As may be seen from FIG. 7, when the time taken for the output of the integrator 830 to decay to the initial value is close (e.g., similar) to the width of the pulse included in the transmission signal, the output of the integrator 830 may be close (e.g., similar) to the output of an ideal integrator. As used herein, the ideal integrator may refer to an integrator for implementing a convolution operation. According to the disclosure, by considering that the waveforms of the transmission signal and the reception signal are pre-known, the impedance values of the passive elements of the integrator 830 may be suitably adjusted and accordingly the convolution operation may be replaced with the integration operation.

According to an embodiment, the LiDAR device 800 may further include an adjustment circuit for changing the impedance values of the plurality of passive elements in real time in response to a change in the width of a pulse included in the transmission signal.

The adjustment circuit may include a switch circuit for changing the impedance value of the passive element and a serial peripheral interface (SPI) for receiving and/or transmitting a signal for controlling the switch circuit. However, the disclosure is not limited thereto, and the adjustment circuit may further include other components and/or may include other types of interfaces.

The impedance value of the passive element suitable for the changed width of the pulse may be determined by an external processor (e.g., DSP) and the external processor may transmit a command for changing impedance value to the serial peripheral interface. However, the disclosure is not limited thereto. For example, the impedance value of the passive element suitable for the changed width of the pulse may be directly determined by a separate processor included in the adjustment circuit. The width of the pulse included in the transmission signal may be changed, and in this case, because the adjustment circuit may suitably change the impedance values of the plurality of passive elements in real time, the convolution operation by the integrator 830 may be normally performed.

The LiDAR device 800 may further include at least one amplifier for converting and/or amplifying an electric signal. For example, the LiDAR device 800 may include at least one of a TIA for converting a current signal into a voltage signal and/or a VGA for amplifying an electric signal with a variable gain. The TIA may be arranged at the front end of the integrator 830, and/or the VGA may be arranged at any suitable position of the front end and/or the rear end of the integrator 830 or may be integrated with the integrator 830.

Alternatively or additionally, the LiDAR device 800 may further include an ADC for converting an analog signal into a digital signal. The ADC may be arranged at any suitable position of the rear end of the integrator 830. The ADC may be directly connected to the integrator 830. However, the disclosure is not limited thereto. For example, the ADC and the integrator 830 may be connected through a separate element such as an amplifier. By arranging the integrator 830 at the front end of the ADC, the LiDAR device 800, according to the disclosure, may perform a convolution operation in the analog domain. As the convolution operation is performed in the analog domain, the ToF may be rapidly and efficiently calculated. Accordingly, the distance measurement resolution and the scanning speed (e.g., the number of frames per second) of the LiDAR device 800 may be increased.

The LiDAR device 800 may further include a DSP for determining the ToF used to measure a distance to the object based on a digital signal. The DSP may be implemented as an operation processor (e.g., CPU, GPU, NPU, MCU, AP, or the like) including a dedicated logic circuit (e.g., FPGA, ASIC, or the like); however, the disclosure is not limited thereto. The DSP may obtain an actual ToF by subtracting the time corresponding to the half of the width of the transmission signal from the time at which the peak is detected in the digital signal. The DSP may detect the peak by detecting the rising edge and falling edge of the digital signal; however, the disclosure is not limited thereto.

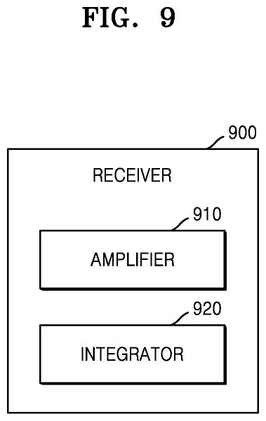

FIG. 9 is a block diagram illustrating a configuration of a receiver, according to an embodiment.

Referring to FIG. 9, a receiver 900 may further include an amplifier 910 and an integrator 920. The receiver 900 may be and/or may include a receiving chip and/or a readout integrated circuit (ROIC) for the LiDAR device. However, the disclosure is not limited thereto. Only components related to the present embodiments are illustrated in the receiver 900 illustrated in FIG. 9. It is to be apparent to those of ordinary skill in the art that the receiver 900 may further include other general-purpose components in addition to the components illustrated in FIG. 9.

The amplifier 910 may obtain a reception signal by converting and/or amplifying an electric signal corresponding to the light reflected from the object. The integrator 920 may obtain an analog signal corresponding to the convolution result between the reception signal and the transmission signal by integrating the reception signal. The transmission signal may be included in the light irradiated to the object, and the analog signal may be used to measure a distance to the object by a ToF method. As an example, the amplifier 910 and the integrator 920 may be integrated into a single chip. Moreover, because the amplifier 910 and the integrator 920 respectively correspond to the amplifier 130 of FIG. 1 and the integrator 830 of FIG. 8, redundant descriptions thereof will be omitted for conciseness

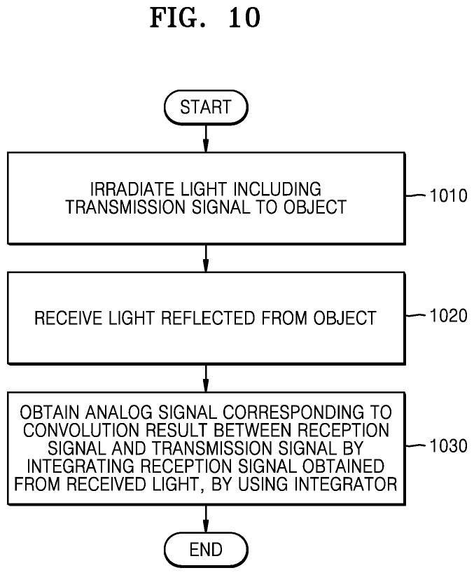

FIG. 10 is a flowchart illustrating an operating method of a LIDAR device, according to an embodiment.

Referring to FIG. 10, an operating method of a LIDAR device according to the disclosure may include operations processed by the LiDAR device 800 of FIG. 8. Thus, even when there are descriptions omitted below, the descriptions given above with respect to FIG. 8 may also be applied to the operating method of the LiDAR device of FIG. 10.

In operation 1010, the LiDAR device may irradiate light including a transmission signal to an object. The transmission signal may include a single pulse or a pulse train of a square wave, and the interval between two adjacent pulses among a plurality of pulses included in the pulse train may be greater than or equal to the width of each of the plurality of pulses.

In operation 1020, the LiDAR device may receive light reflected from the object. Alternatively or additionally, the LiDAR device may obtain a reception signal by obtaining an electric signal from the received light and amplifying and/or converting the electric signal.

In operation 1030, the LiDAR device may obtain an analog signal corresponding to the convolution result between the reception signal and the transmission signal by integrating the reception signal obtained from the received light, by using an integrator. The analog signal may be used to measure a distance to the object by a ToF method.

The LiDAR device may integrate the reception signal during a time interval with a preset time length from past to present by using the integrator. The preset time length may correspond to the width of the pulse included in the transmission signal. The integrator may include at least one active element and a plurality of passive elements, and the impedance values of the plurality of passive elements may be determined such that the time taken for the output of the integrator to decay to an initial value may be close to the width of the pulse included in the transmission signal. According to an embodiment, the LiDAR device may change the impedance values of the plurality of passive elements in real time in response to a change in the width of the pulse included in the transmission signal.

The LiDAR device may convert an analog signal into a digital signal and determine a ToF used to measure a distance to the object based on the digital signal. For example, the LiDAR device may obtain the ToF by subtracting the time corresponding to the half of the width of the transmission signal from the time at which the peak is detected in the digital signal.

According to the disclosure, by considering that the waveforms of the transmission signal and the reception signal are pre-known, the impedance values of the passive elements of the integrator may be suitably adjusted and accordingly a convolution operation may be replaced with an integration operation. Alternatively or additionally, according to the disclosure, the LiDAR device may perform a convolution operation in the analog domain. As the convolution operation is performed in the analog domain, the ToF may be rapidly and efficiently calculated. Accordingly, the distance measurement resolution and the scanning speed (e.g., the number of frames per second) of the LiDAR device may be increased.

The operating method of the LiDAR device described above may be recorded on a computer-readable recording medium on which one or more programs including instructions for executing the operating method are recorded. Examples of the computer-readable recording medium include magnetic media such as, but not limited to, hard disks, floppy disks, and magnetic tapes, optical media such as compact disk ROMs (CD-ROMs) and digital versatile discs (DVDs), magneto-optical media such as floptical disks, and hardware devices such as ROMs, RAMs, and flash memories that are specially configured to store and execute program instructions. Examples of the program instructions include not only machine language codes such as those generated by compilers, but also high-level language codes that may be executed by computers by using interpreters or the like.

It is to be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it may be understood by those of ordinary skill in the art that various changes in form and details may be made therein without departing from the spirit and scope as defined by the following claims.

What is claimed is:

1. A device for performing light detection and ranging (LiDAR), comprising:
a light transmitter configured to radiate, to an object, light comprising a transmission signal;
a light receiver configured to receive light reflected from the object;
an integrator configured to obtain, by integrating a reception signal obtained from the received light, an analog signal corresponding to a convolution result between the reception signal and the transmission signal; and
a processor configured to measure, by a time-of-flight (ToF) method, a distance from the device to the object, based on the analog signal.

2. The device of claim 1, wherein:
the transmission signal comprises at least one of a single pulse and a pulse train of a square wave, and
an interval between adjacent pulses among a plurality of pulses comprised by the pulse train is greater than or equal to a width of each pulse of the plurality of pulses.

3. The device of claim 1, wherein:
the integrator is further configured to integrate the reception signal during a sliding time interval with a preset time length, and
the preset time length corresponds to a width of a transmitted pulse comprised by the transmission signal.

4. The device of claim 1, wherein:
the integrator comprises at least one active element and a plurality of passive elements, and
impedance values of the plurality of passive elements are determined such that a decay time needed for an output of the integrator to decay to an initial value is similar to a width of a transmitted pulse comprised by the transmission signal.

5. The device of claim 4, wherein:
the at least one active element comprises at least one operational amplifier, and
the plurality of passive elements comprises at least one resistor and at least one capacitor.

6. The device of claim 4, further comprising:
an adjustment circuit configured to change the impedance values of the plurality of passive elements in response to a change in the width of the transmitted pulse comprised by the transmission signal.

7. The device of claim 1, wherein:
the light receiver comprises at least one light receiving element configured to convert the received light into an electric signal, and
the device further comprises at least one amplifier configured to amplify the electric signal.

8. The device of claim 1, further comprising:
an analog-to-digital converter (ADC) configured to convert the analog signal into a digital signal.

9. The device of claim 8, wherein the processor is further configured to:
determine a ToF used to measure the distance from the device to the object, based on the digital signal.

10. The device of claim 9, wherein the processor is further configured to:
obtain the ToF by subtracting a first time point corresponding to half of a width of the transmission signal from a second time point at which a peak is detected in the digital signal.

11. A receiving device for performing light detection and ranging (LiDAR), the receiving device comprising:
an amplifier configured to obtain a reception signal by converting and amplifying an electrical signal corresponding to light reflected from an object; and
an integrator configured to obtain an analog signal corresponding to a convolution result between the reception signal and a transmission signal by integrating the reception signal,
wherein the transmission signal is included in light radiated to the object and the analog signal is used to measure a distance from the receiving device to the object by a time-of-flight (ToF) method.

12. The receiving device of claim 11, wherein the amplifier and the integrator are integrated into a single chip.

13. An operating method of a device for performing light detection and ranging (LIDAR), the operating method comprising:
radiating, to an object, light comprising a transmission signal;
receiving light reflected from the object;
obtaining, by using an integrator to integrate a reception signal obtained from the received light, an analog signal corresponding to a convolution result between the reception signal and the transmission signal; and
measuring, by a time-of-flight (ToF) method, a distance from the device to the object, based on the analog signal.

14. The operating method of claim 13, wherein:
the transmission signal comprises at least one of a single pulse and a pulse train of a square wave, and
an interval between adjacent pulses among a plurality of pulses comprised by the pulse train is greater than or equal to a width of each pulse of the plurality of pulses.

15. The operating method of claim 13, wherein the obtaining of the analog signal comprises:
integrating the reception signal during a sliding time interval with a preset time length,
wherein the preset time length corresponds to a width of a transmitted pulse comprised by in the transmission signal.

16. The operating method of claim 13, further comprising:
determining impedance values of a plurality of passive elements of the integrator such that a decay time needed for an output of the integrator to decay to an initial value is similar to a width of a transmitted pulse comprised by the transmission signal.

17. The operating method of claim 16, further comprising:
changing the impedance values of the plurality of passive elements in response to a change in the width of the transmitted pulse comprised by the transmission signal.

18. The operating method of claim 13, further comprising:
converting the analog signal into a digital signal.

19. The operating method of claim 18, further comprising:
determining a ToF used to measure the distance from the device to the object based on the digital signal.

20. The operating method of claim 19, wherein the determining of the ToF comprises:
obtaining the ToF by subtracting a first time point corresponding to half of a width of the transmission signal from a second time point at which a peak is detected in the digital signal.
